(19) United States
(12) Patent Application Publication
(10) Pub. No.: US 2008/0174500 A1
(43) Pub. Date: Jul. 24, 2008

(54) MAGNETIC COMMUNICATION LINK WITH DIVERSITY ANTENNAS

(75) Inventor: James Turner, Snohomish, WA (US)

Correspondence Address: MERCHANT & GOULD (MICROSOFT), P.O. BOX 2903, MINNEAPOLIS, MN, 55402-0903, US

(73) Assignee: Microsoft Corporation, Redmond, WA (US)

(21) Appl. No.: 11/626,262

(22) Filed: Jan. 23, 2007

(51) Int. Cl. H01Q 3/00; H01Q 9/00; G01R 29/08

(52) U.S. Cl. 343/703; 343/757; 343/745

(57) ABSTRACT

To adjust operating characteristics of a first antenna and a second antenna to receive a magnetic signals transmitted by a third antenna, a first magnetic signal from the first antenna. The first magnetic signal is received at the third antenna. A second magnetic signal is transmitted from the second antenna. The second magnetic signal is received at the third antenna. A gain of the first antenna is adjusted in response to an indication of signal quality of the first magnetic signal received at the third antenna. A gain of the second antenna is also adjusted in response to an indication of signal quality of the second magnetic signal received at the third antenna.

### BACKGROUND

Using magnetic link communications in portable electronic devices is problematic because magnetic link devices are sensitive to position. In portable devices, the magnetic link transmitter and receiver may not move relative to each other during use, and changes in relative position and orientation between the devices can significantly diminish the received signal quality. Unless the magnetic link can overcome the diminished signal quality, communication quality may suffer or fail.

In addition to the signal loss due to changes in relative position of transmit and receive devices, signal loss may also be due to changes in the operating environment. For example, if a magnetic link is moved near ferromagnetic material, such as metal in a car, the frequency tuning of the antenna may be altered. An antenna without optimal frequency tuning, may suffer from a drop in efficiency and signal quality will be lost. Thus, both changes in relative position and in operating environment may diminish signal quality in the magnetic link and lead to a reduction in overall communication quality.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

The present disclosure is directed to devices, methods and system for magnetic communication that balances gain of diversity antennas and allows automatic tuning of the antennas. Specifically, a base unit and a remote unit may communicate through a magnetic link. The base unit may include diversity antennas to increase the signal quality of the magnetic communication link. The diversity antennas may be individually tuned to adjust for environmental changes. The magnetic link communication efficiency of the various antennas may also be tested. Following the communication efficiency test, the transmit and receive gains of the antennas are balanced.

In an implementation of a system for receiving a magnetic communication, the system includes a first antenna configured to receive a first magnetic signal. The system also includes a second antenna configured to receive the first magnetic signal, wherein the second antenna is oriented at an angle to the first antenna. In addition, the system includes a first control unit adapted to adjust a first receive gain of the first antenna and a second receive gain of the second antenna in response to an indication of a signal quality detected at the first antenna, the second antenna, or a combination of the first antenna and the second antenna.

In an implementation of a method of adjusting operating characteristics of a first antenna and a second antenna to receive magnetic signals transmitted by a third antenna, the method includes transmitting a first magnetic signal from the first antenna. The first magnetic signal is received at the third antenna. A second magnetic signal is transmitted from the second antenna and is received at the third antenna. A gain of the first antenna is adjusted in response to an indication of signal quality of the first magnetic signal received at the third antenna. Additionally, a gain of the second antenna is also adjusted in response to an indication of signal quality of the second magnetic signal received at the third antenna.

In an implementation of a method of using a first antenna to communicate a magnetic signal, the method includes providing a variable capacitor coupled to the first antenna. A signal is then provided to the first antenna. A resulting voltage is measured across the first antenna. The variable capacitor is adjusted to maximize the resulting voltage across the first antenna. The magnetic signal is communicated with the antenna.

These and other features and advantages will be apparent from reading the following detailed description and reviewing the associated drawings. It is to be understood that both the foregoing general description and the following detailed description are explanatory only and are not restrictive. Among other things, the various embodiments described herein may be embodied as methods, devices, or a combination thereof. Likewise, the various embodiments may take the form of an entirely hardware embodiment, an entirely software embodiment or an embodiment combining software and hardware aspects. The disclosure herein is, therefore, not to be taken in a limiting sense.

### BRIEF DESCRIPTION OF THE DRAWINGS

In the drawings, like numerals represent like elements. In addition, the first digit in the reference numerals refers to the figure in which the referenced element first appears.

FIG. 1 is diagram illustrating an exemplary system for magnetic communication;

FIGS. 2A-2B are diagrams illustrating different relative orientations of a base unit and a remote unit;

FIG. 3 is a schematic diagram illustrating exemplary implementations of a base unit and remote unit;

FIG. 4 is a flow diagram illustrating an exemplary process of a self-calibration procedure;

FIG. 5 is a flow diagram illustrating an exemplary process for automatically tuning the antennas;

FIG. 6 is a flow diagram illustrating an exemplary process for testing antenna communication efficiency;

FIG. 7 is a flow diagram illustrating an exemplary process for testing antenna communication efficiency;

FIG. 8 is a flow diagram illustrating an exemplary process for setting antenna gains; and

FIG. 9 is a block diagram of an operating environment for implementations of computer-implemented methods as herein described.

### DETAILED DESCRIPTION OF IMPLEMENTATIONS

This detailed description describes implementations of a magnetic communication link with diversity antennas. Generally, a magnetic link is used in the following exemplary description to provide communication between antennas in a base unit and a remote unit. The base unit may have a plurality of antennas and the ear unit may have at least one antenna. In one implementation, self-calibration of the base unit is conducted before communication is initiated. In other implementations, self-calibration may be conducted at regular intervals during communication. Self-calibration may begin with the automatic tuning of each antenna. In addition, the gains of the plurality of base unit antennas may be set to optimize signal quality and power consumption.

### Exemplary Implementation of Magnetic Link

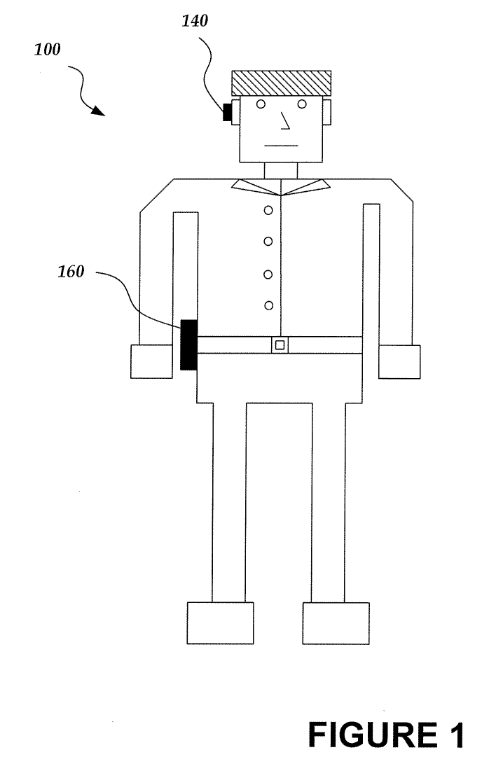

FIG. 1 shows an operating environment 100 of a magnetic link system for communicating with a magnetic communication link. The operating environment 100 may contain a remote unit 140 and a base unit 160. The remote unit 140 may, for example, be a smaller unit configured to be worn as an earpiece.

The base unit 160 may be a unit with a larger form factor than the remote unit 140. The base unit 160 may, for example, be similar in size to that of a standard cellular phone hand set or a personal data organizer (PDA) in order to be worn on the hip of a user. In other embodiments, the base unit 160 may be significantly smaller or significantly larger than a PDA or cellular phone handset. Because the base unit 160 may have a large form factor, it may contain multiple antennas. In some embodiments the base unit may be included in a PDA, a cell phone or a desk top phone. In other embodiments, the base unit may be included in a larger device, such as an automobile.

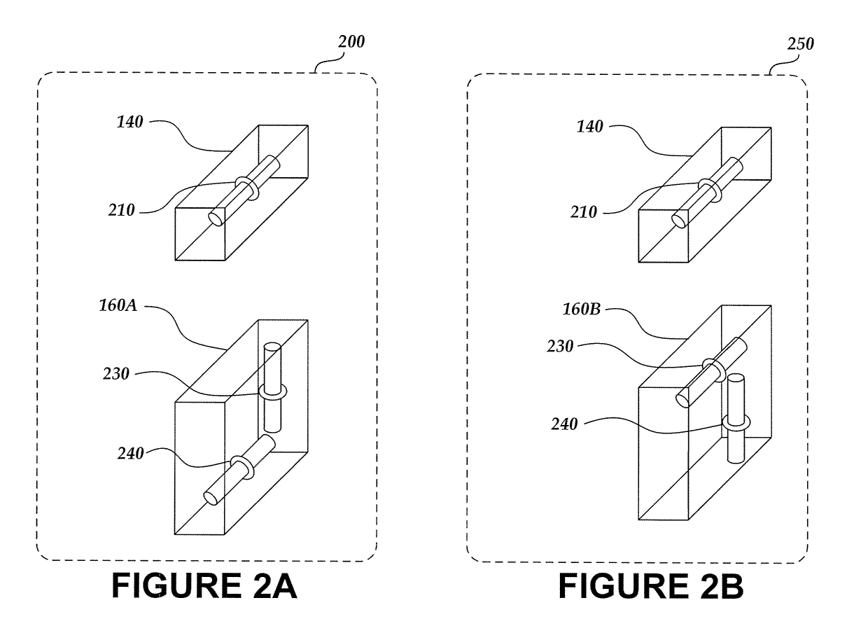

FIGS. 2A and 2B show operating environments 200 and 250. The operating environment 200 of FIG. 2A shows the remote unit 140 and a base unit 160A. The remote unit 140 contains a remote unit antenna 210. The base unit 160A contains a first base unit antenna 230 and a second base unit antenna 240. In the operating environment 200, the first base unit antenna 230 is parallel to the remote unit antenna 210 and the second base unit antenna 240 is perpendicular to the remote unit antenna 210. The operating environment 250 of FIG. 2B shows the remote unit 140 and a base unit 160B. The base unit 160B may be similar to the base unit 160A and contain the first base unit antenna 230 and the second base unit antenna 240. In the operating environment 250, the base unit 160B is rotated 90 degrees in relation to the base unit 160A. Thus, in the operating environment 250 the first base unit antenna 230 is now perpendicular to the remote unit antenna 210 and the second base unit antenna 240 is now parallel to the remote unit antenna 210.

It may be desirable to use multiple antennas in the base unit 160 and/or the remote unit 140 because of the directional nature of magnetic link signals. For example, if a magnetic link antenna in a receiver is perpendicular to an antenna transmitting the signal, the antenna will receive the signal very poorly, if at all. On the other hand, if the antenna in the receiver is parallel to the antenna transmitting the signal, the antenna will receive a much stronger signal. Thus, by using multiple antennas arrayed at an angle to each other in a receiver, it is more likely that at least one of the antennas will be oriented so as to be able to receive a transmitted signal.

Similarly, by using multiple antennas arrayed at an angle to each other in a transmitter, it is more likely that at least one of the antennas will be oriented such that it transmits a signal that may be received by a receiver. For example, in a magnetic link communication system, a magnetic signal may be transmitted from a first antenna and received at a second antenna. If the orientation of each antenna is fixed, when the magnetic signal is transmitted from the first antenna in a direction in which the second antenna may receive the signal at a high efficiency, the system will function properly.

On the other hand, problems may occur if one of the antenna positions is altered, and the antennas are no longer optimally positioned. In that case, magnetic communication efficiency will then be decreased. By using a sufficient number of diversity antennas in the base unit 160, positioned in sufficiently different directions, the communication link will be maintained despite changes in orientation between the transmitting unit and the receiving antenna. In other embodiments, both the remote unit 140 and the base unit 160 may use diversity antennas.

To determine the number of diversity antennas needed, the manner in which the system will be used may be considered. The specific manner in which a system will be used may restrict relative motion between units. By restricting movement, fewer antennas may be needed to maintain a communication link. For example, in the exemplary implementation shown in operating environment 100, the remote unit 140 functions as an earpiece mounted behind the ear of a user. Because the remote unit 140 is functioning as an earpiece fixed to the ear of a user, it is unlikely the remote unit 140 will move independent of the user's head. In addition, the base unit 160 is configured to be worn on the belt of the user. Because the base unit 160 is functioning as a device worn on the belt, it is unlikely the base unit 160 will move independent of the user's hips.

The relative motion between the base unit 160 and the remote unit 140 is therefore restricted to the range of movements natural to the body of the user. The number of antennas needed is thereby reduced because the antennas of the base unit 160 and the remote unit 140 will not be placed in any arbitrary position, but rather only in positions within the range of motion of the user's body. In other implementations, system use may restrict motion beyond that described above and therefore further reduce the number of antennas required. In still other implementations, system use may not restrict motion between the base unit 160 and the remote unit 140, and thus the number of needed diversity antennas will be increased beyond that described above.

Similarly, an additional consideration in determining the number of diversity antennas to be used is the form factor of the individual units of the magnetic link. For example, in some implementations the base unit 160 may be relatively flat and have a form factor that is smaller in one dimension than in the other two dimensions, such as the shape of a standard PDA. A relatively flat base unit would tend to be carried by the user in orientations in which it lays flat against the body. For example, such a shape would allow the base unit 160 to be conveniently worn on the belt or in the pocket of a user. On the other hand, it would be less convenient for a user to carry the base unit 160 when it is not flat against their the body because in such an orientation it would no longer fit in a shirt pocket or be capable of being clipped on a belt.

Based on the limitations form factor places on the position of the base unit 160, the relative motion between the base unit 160 and the remote unit 140 is further restricted. The number of antennas needed is thereby reduced because it may be predicted that the antennas of the base unit 160 and the remote unit 140 will not be placed in positions where the base unit 160 is not flat against the body of the user. In other implementations, form factor may restrict position beyond that described above and therefore further reduce the number of antennas required. In still other implementations, form factor may not restrict position between the base unit 160 and the remote unit 140, and thus the required number of diversity antennas will be increased beyond that described above.

Although shown for exemplary purposes to include two antennas, the base unit 160 may include any number of antennas. For example, if rotation about multiple dimensions may occur, three antennas oriented in different dimensions may be used. Further, the orientation of the antennas may be varied according to internal space considerations. For example, two perpendicular antennas are shown in a base unit 160 that is relatively flat in FIGS. 2A and 2B. In other examples where the base unit may not be flat, there may be internal space for three mutually perpendicular antennas. In still other examples, multiple smaller antennas may be in parallel to increase gain. In yet other examples, antennas may be at any other angle to each other. The remote unit may similarly contain multiple antennas oriented in different positions.

FIG. 2A shows an environment 200 in which the base unit 160A is in a first position in relation to the remote unit 140. In environment 200, the first base unit antenna 230 is parallel to that of the remote unit antenna 210. Thus, a magnetic signal may efficiently be communicated between the first base unit antenna 230 and the remote unit antenna 210. On the other hand, the second base unit antenna 240 is perpendicular to the remote unit antenna 210 and thus a magnetic signal may not efficiently be communicated between the second base unit antenna 240 and the remote unit antenna 210. In this relative position, although one antenna may not function efficiently, based on position diversity and the use of two antennas, a magnetic communication may still be maintained between the base unit 160 and the remote unit 140.

FIG. 2B shows an environment 250 where the base unit 160 is oriented in a different position than that shown in FIG. 2A. Specifically, in the environment 250, the base unit 160 has been rotated 90 degrees relative to that of the environment 200. Thus, the position of both the first base unit antenna 230 and the second base unit antenna 240 has changed relative to the position of the remote unit antenna 210. Here, the first base unit antenna 230 is no longer parallel, but is now perpendicular to that of the remote unit antenna 210 and a magnetic signal may no longer efficiently be communicated between the first base unit antenna 230 and the remote unit antenna 210. On the other hand, the second base unit antenna 240 is now parallel to the remote unit antenna 210 and a magnetic signal may now efficiently be communicated between the second base unit antenna 240 and the remote unit antenna 210. In this relative position, although one antenna may not function efficiently, a magnetic communication may still be maintained through use of diversity antennas.

In other examples, the base unit 160 may rotate in a position in which neither the first base unit antenna 230 nor the second base unit antenna 240 are parallel to the remote unit antenna 210 and neither are perpendicular to the remote unit antenna 210. In such a case, neither antenna will communicate with a maximum efficiency and neither will communicate with a minimum efficiency. Thus, both antennas may be used in combination to communicate with the remote unit antenna 210. In such a case, based on position diversity, through the use of two antennas a magnetic communication may still be maintained.

### Operation of Base Unit and Remote Unit in a Magnetic Link Environment

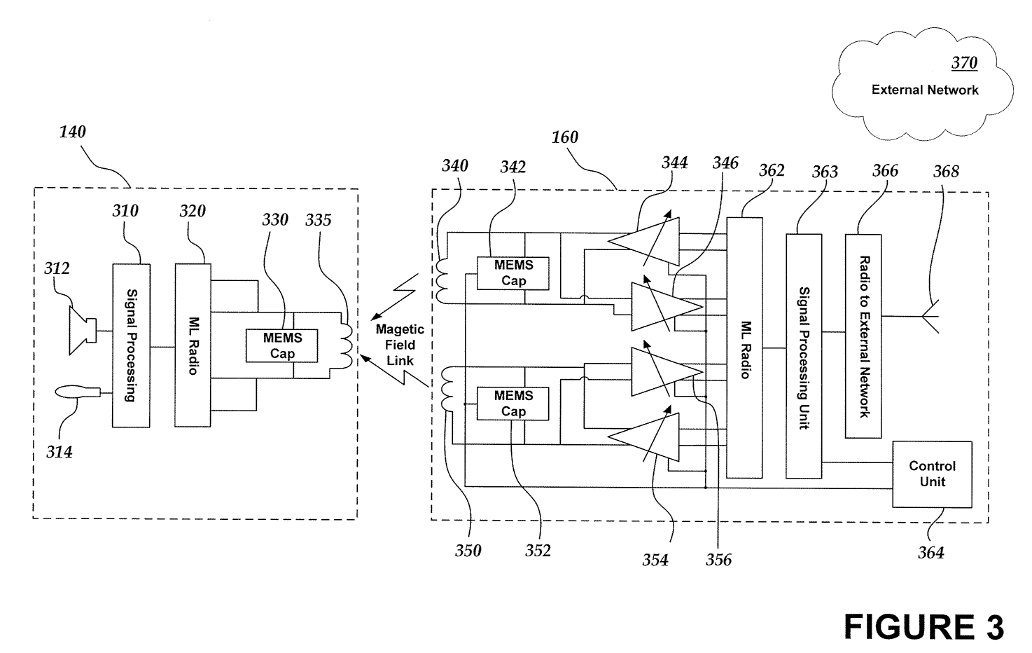

FIG. 3 shows an exemplary magnetic link environment 300 for the base unit 160 and the remote unit 140. The remote unit 140 contains a microphone 312 and a speaker 314 that allow a user to communicate via the base unit 160 and the remote unit 140. The microphone 312 and the speaker 314 are coupled to a signal processor 310 which may in turn be coupled to a magnetic link radio 320. A variable micro-electromechanical systems (MEMS) capacitor 330 and a magnetic link remote unit antenna 335 may be coupled across transmit outputs of the signal processor 310. The magnetic link remote unit antenna 335 may be similar to the remote unit antenna 210. The radio 320 may be configured to receive a signal from inputs connected across the capacitor 330 and the remote unit antenna 335.

The remote unit antenna 335 may communicate magnetically with the base unit 160 through a first base unit antenna 340 and a second base unit antenna 350. The first base unit antenna 340 and the second base unit antenna 350 may be similar to the first base unit antenna 230 and the second base unit antenna 240. The base unit may contain variable MEMS capacitors 342 and 352 connected respectively across the first base unit antenna 340 and the second base unit antenna 350. The first base unit antenna 340 may further be coupled to the output of a transmit amplifier 344 and the inputs of a receive amplifier 346. The output of the receive amplifier may in turn be coupled to a magnetic link radio 362. The inputs of the transmit amplifier 344 may also be coupled to the magnetic link radio 362. Similarly, the second base unit antenna 350 may be coupled to the output of a transmit amplifier 356 and the inputs of a receive amplifier 354. The outputs of the receive amplifier 354 may in turn be coupled to the magnetic link radio 362. The inputs of the transmit amplifier 356 may also be coupled to the magnetic link radio 362.

The radio 362 may be coupled to a signal processing unit 363. The signal processing unit 363 may then be coupled to an external network radio 366. The signal processing unit 363 may also be coupled to a control unit 364. The control unit may be coupled to gain controls on the amplifiers 344, 346, 354 and 356 to control their gain. The control unit 364 may also be coupled to the variable MEMS capacitors 342 and 352 such that their capacitance may be controlled. The radio 366 may communicate through an external network antenna 368. The external network antenna 368 may transmit signals to, or receive signals from, an external network 370.

For example, a signal may be transmitted from the external network 370 to the antenna 368. The antenna 368 may then communicate the signal to the radio 366, which in turn processes it and communicates it to the signal processing unit 363. The signal processing unit 363 may then further process the signal and transmit it to the magnetic link radio 362. The magnetic link radio 362 may then input the signal into the transmit amplifiers 344 and 346. The transmit amplifiers 344 and 346 may amplify the signal and communicate it to the first base unit antenna 340 and the second base unit antenna 350. The first base unit antenna 340 and the second base unit antenna 350 then transmit a magnetic signal from the base unit 160.

The magnetic signal may be received by the remote unit antenna 335 of the remote unit 140. The signal may then be supplied to the radio 320. The radio 320 may then transmit the signal to the signal processor 330 where it may be processed and transmitted to the speaker 312. The speaker 312 may then communicate the signal to the user.

In response, the user may supply another signal into the microphone 314. The microphone 314 may then transmit the input signal to the signal processor 310 where it is processed and provided to the radio 320. The radio 320 may then drive the remote unit antenna 335 with the signal. The remote unit antenna 335 may then transmit a magnetic link containing the signal from the remote unit 140.

The first base unit antenna 340 and the second base unit antenna 350 may then receive the signal and supply it to the receive amplifiers 346 and 354. The receive amplifiers 346 and 354 may amplify the signal and provide it to the radio 362. The radio 362 can then transmit the signal to the signal processing and control circuit 364 that processes the signal and supplies it to the radio to the external network 366. The radio 366 can then transmit the signal from the antenna 368 to the external network 370.

### Self-Calibration of the Antennas

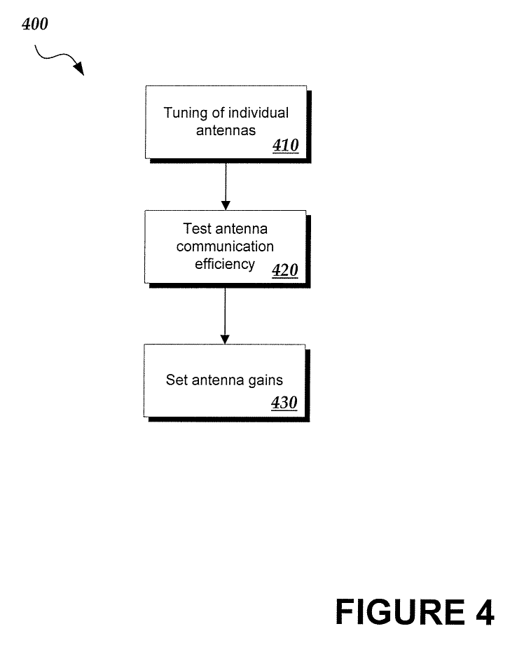

FIG. 4 presents a flow diagram 400 of an implementation for a self-calibration procedure. Self-calibration may occur when the system is first initiated, and may also occur at regular time intervals when the communication link is not being actively used. At 410, the process 400 begins where the tuning of the antenna occurs. Tuning can be conducted because each antenna may be constructed to operate over a defined frequency range centered about a center frequency. Although the antennas may be properly tuned during construction such that the antenna center frequency corresponds with the nominal operational center frequency, this center frequency may be altered by environmental factors. For example, a user may bring the base unit or remote unit near ferromagnetic material, such as metal in a car door. Such environmental changes affect the inductance and capacitance of the antenna resulting in a shift of the antenna center frequency. Thus, when the antenna center frequency and the operational center frequency differ, performance will suffer and reception and transmission efficiency will be reduced. Because of this, each antenna must be tuned to calibrate for these environmental variations.

At 420, antenna communication efficiency is tested. In general, magnetic antennas may be directional. For example, a magnetic antenna may receive or transmit a first direction component of a magnetic field at a first efficiency, and other direction components of the magnetic field at much lower other efficiencies. Thus, although two magnetic antennas may communicate efficiently when oriented in parallel to each other, such as antennas 240 and 210 of FIG. 2A, in consumer equipment the relative positions between antennas may not be fixed. For example, the antennas may rotate relative to each other, as shown in FIGS. 2A and 2B. Thus, at 420 the communication efficiency of the antenna pairs must be tested to determine which antennas should be used.

After the communication efficiency of the antennas is tested at 420, the flow diagram 400 continues to 430. At 430, the individual gains are balanced in response to the tested antenna communication efficiency, as further explained below.

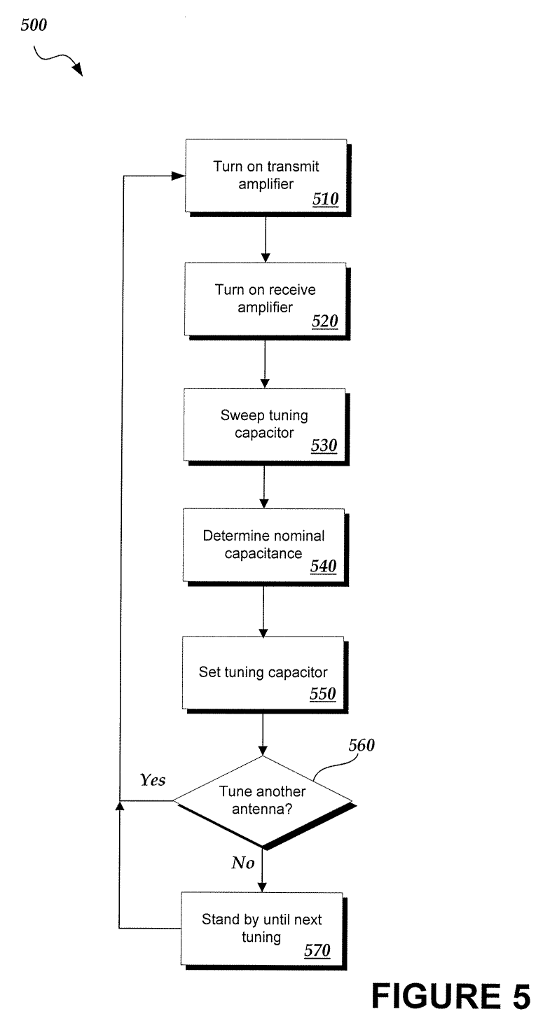

FIG. 5 presents a flow diagram 500 of an exemplary procedure for automatically tuning the antennas as invoked at 410 of FIG. 4. At 510, a first transmit amplifier, such as transmit amplifier 344, is turned on and a test signal is sent to an associated antenna, such as antenna 340. This test signal may, for example, be a constant magnitude alternating current signal at the operational center frequency. Once the transmit amplifier is activated to transmit the test signal at 510, at 520 a receive amplifier associated with the antenna is also turned on, such as the receive amplifier 346. The receive amplifier 346 may be constructed to measure the voltage across the first base unit antenna 340. Once the proper amplifier has been set to monitor the voltage across the antenna being tuned at 520, at 530 a variable capacitor associated with the antenna being tuned is swept through a test range of capacitance values. In one implementation the variable capacitor may include a MEMS capacitor, such as MEMS capacitor 342.

After the capacitance of the variable capacitor has been swept through the test range, the nominal capacitance is determined at 540. The nominal capacitance is the capacitance in which the greatest voltage is received at the receive amplifier during the test, with the addition of a correction factor. The correction factor may, for example, account for any differences in operating characteristics of the antenna and corresponding amplifiers during test and during operation. Following a determination of the nominal capacitance at 540, the variable capacitor is set to the nominal capacitance at 550.

At 560, a determination is made as to whether another antenna needs to be tuned. If there is another antenna that needs to be tuned, the flow diagram 500 returns to 510, where the procedure is repeated for each antenna. If there are no more antennas to be tuned, the flow diagram 500 continues to 570. At 570, the tuning process stands by until the next antenna tuning. For example, tuning may be accomplished as part of a start-up sequence, or in other implementations, tuning may be accomplished after a specific amount of communication. In still other implementations tuning may be executed at a measured break in communication. This process thus allows each antenna can be individually tuned.

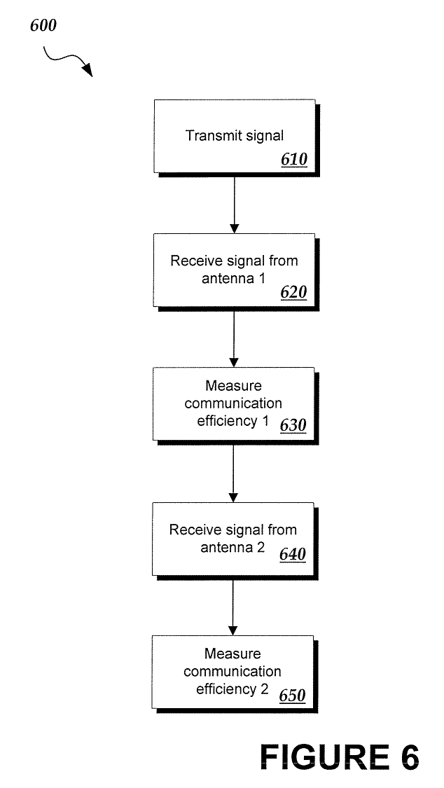

FIG. 6 presents a first exemplary process 600 for testing antenna communication efficiency as invoked at 420 of FIG. 4. Antenna communication efficiency is the efficiency in which an antenna pair communicates. An antenna pair may include a transmit antenna and a receive antenna. At 610, the diagram of the process 600 begins where a test signal is transmitted from a transmit antenna, such as the remote unit antenna 210 of the remote unit 140. The test signal may, for example, include a standard communication signal or it may include a specialized test signal transmitted at a high power. A test signal transmitted at a high power may increase the likelihood a signal will be received.

At 620, the test signal may be received at a first receive antenna, such as the first base unit antenna 230 of the base unit 160A. At 630, the relative antenna communication efficiency between the first antenna pair is measured. For example, the antenna communication efficiency between the remote unit antenna 210 and the first base unit antenna 230 is measured based on the quality of the signal received at the first base unit antenna 230. At 640, the test signal may additionally be received at a next receive antenna, such as the second base unit antenna 240 of the base unit 160A. At 650, the relative antenna communication efficiency between the second antenna pair is determined.

For example, the antenna communication efficiency between the remote unit antenna 210 and the second base unit antenna 240 is measured based on the quality of the signal received at the second base unit antenna 240. In some implementations the signal quality may be determined with reference to signal strength. In other implementations, signal quality may be determine with reference to any other indication of signal quality, such as a channel state estimator or bit error rate. Although shown as separate steps in the flow diagram 600, because the signal may be received at multiple antennas simultaneously, steps 640 and 650 may be performed simultaneously with steps 620 and 630.

Further, although both receive antennas may be located at approximately the same linear distance from the transmit antenna, as each receive antenna may be positioned differently in relation to the positioning of the transmit antenna, the received signal strengths may differ. For example, the first base unit antenna 230 may be positioned perpendicular to the remote unit antenna 210 and, in contrast, the second base unit antenna 240 may be positioned parallel to the remote unit antenna 210. This difference in relative position may affect the strength of the signal received at each antenna. Thus, different antenna efficiencies may be measured through process 600 by using multiple receive antennas to receive a signal transmitted from a common source. In this example, a single transmit antenna and two receive antennas were described. In other examples, multiple transmit antennas and more than two receive antenna may also be used.

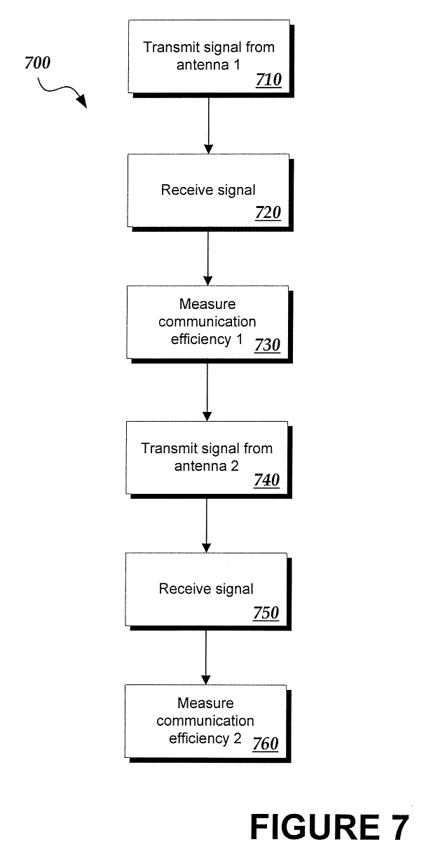

FIG. 7 presents another exemplary process 700 for testing antenna communication efficiency, as invoked at 420 of FIG. 4. In contrast to the process 600, the process 700 transmits a signal at a common strength from multiple transmit antennas and receives the signal at a single receive antenna. At 710, the process 700 begins where a first test signal is transmitted from a first transmit antenna, such as the first base unit antenna 230 of the base unit 160A. The test signal may, for example, include a standard communication signal or it may include specialized test signal transmitted at a high power. A test signal transmitted at a high power may increase the likelihood a signal will be received. At 720, the first test signal may be received by a receive antenna, such as the remote unit antenna 210 of the remote unit 140. At 730, the relative antenna communication efficiency between the first antenna pair is determined. For example, the antenna communication efficiency between the first base unit antenna 230 and the remote unit antenna 210 may be measured based on the quality of the signal transmitted from the first base unit antenna 230 that is received at the remote unit antenna 210.

At 740, a second test signal may be transmitted from a next transmit antenna, such as the second base unit antenna 240 of the base unit 160A. This test signal may be a signal with the same characteristics as the first test signal transmitted from the first transmit antenna. At 740, the second signal test may be received by the receive antenna. At 750, antenna communication efficiency between the second antenna pair is determined. For example, the antenna communication efficiency between the second base unit antenna 240 and the remote unit antenna 210 is measured based on the quality of the signal transmitted from second base unit antenna 240 that is received at the remote unit antenna 210.

In the foregoing examples, transmit and receive gains were set based on relative communication efficiencies of antenna pairs. In other implementations, gains may be set based on absolute communication efficiencies. In still other implementations the gains may be balanced based upon a combination of such methods.

Although both transmit antennas may be located at approximately the same linear distance from the common receive antenna, as each transmit antenna may be positioned differently in relation to the positioning of the receive antenna the received signal strength of each test signal may differ. For example, the first base unit antenna 230 may be positioned perpendicular to the remote unit antenna 210 and, in contrast, the second base unit antenna 240 may be positioned parallel to the remote unit antenna 210. This difference in relative positions may result in a variance in the strength of each signal received at the receive remote unit antenna 210. Thus, antenna communication efficiency may be determined through the process 700 by measuring qualities of the signals received at a single receive antenna when a common signal was transmitted from multiple transmit antennas. In this example, a single receive antenna and two transmit antennas were described. In other example, multiple receive antennas and more than two transmit antenna may also be used. In some implementations the signal quality may be determined with reference to signal strength. In other implementations, signal quality may be determine with reference to any other indication of signal quality, such as a channel state estimator or bit error rate.

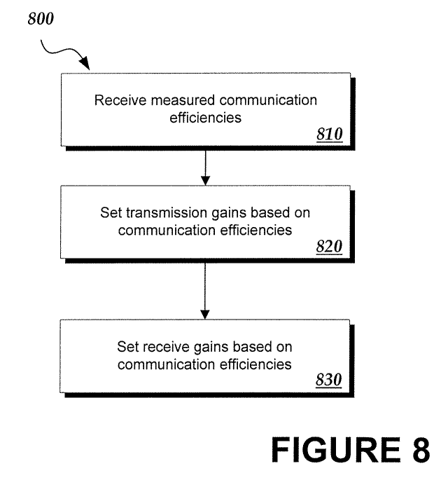

FIG. 8 presents an exemplary process 800 for setting antenna gains, as invoked at 430 of FIG. 4. At 810, the antenna communication efficiencies that were measured are received. At 820, the transmit gains are set in response to the antenna communication efficiencies received. If two antenna pairs are present, such as a first antenna pair including the remote unit antenna 210 and the first base unit antenna 230, and a second antenna pair including the remote unit antenna 210 and the second base unit antenna 240, transmit gains may be set based on the relative antenna communication efficiencies of the pairs. For example, the first antenna pair communication efficiency may be twice that of the second antenna pair communication efficiency. In such a case, the transmit gain of the first antenna pair will be set to twice that of second antenna pair transmit gain. By reducing the transmit power of an antenna that has a low communication efficiency, power may be conserved. Transmit gain may be controlled, for example, by the control unit 364 adjusting the gains of transmit amplifier 344 and 356.

At 830, receive gains are set. Similar to the transmit gains, the receive gains are set in response to the antenna communication efficiencies received. If two antenna pairs are present, such as a first antenna pair including the remote unit antenna 210 and the first base unit antenna 230, and a second antenna pair including the remote unit antenna 210 and the second base unit antenna 240, receive gains may also be set based on the relative antenna communication efficiencies of the pairs. For example, the first antenna pair communication efficiency may be twice that of the second antenna pair communication efficiency. In such a case, the first antenna pair receive gain would be set to twice that of second antenna pair receive gain.

By setting the gains in the manner the receive gain of antennas with a low communication efficiency may be reduced and the receive gain of antennas with a high communication efficiency may be increased. For a given signal transmit power, the signal-to-noise ratio of a received signal at an antenna with a low communication efficiency will be greater than a corresponding signal-to-noise ratio of the received signal at an antenna with a high communication efficiency. Thus, by modifying the receive gains of the various antennas in proportion to their communication efficiency, total system noise may be reduced. Receive gain may be controlled, for example by adjusting the gains of receive amplifiers 346 and 354.

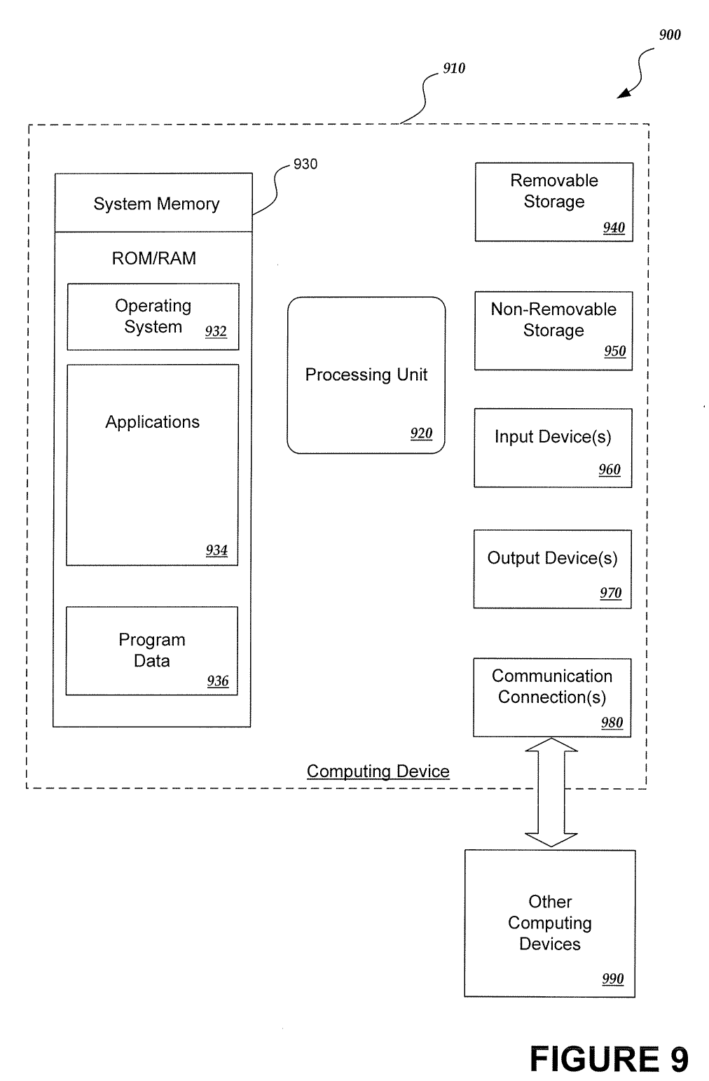

Implementations of a control system for executing the process 400 may be supported by a number of computerized devices to automate the process. FIG. 9 is a block diagram of a representative operating environment 900 for executing the process 400.

Referring to FIG. 9, an exemplary operating environment 900 for executing the process 400 includes a computing device, such as a computing device 910. In a basic configuration, the computing device 910 may include a stationary computing device or a mobile computing device. The computing device 910 typically includes at least one processing unit 920 and system memory 930. Depending on the exact configuration and type of computing device, the system memory 930 may be volatile (such as RAM), non-volatile (such as ROM, flash memory, and the like) or some combination of the two. The system memory 930 typically includes an operating system 932, one or more applications 934, and may include program data 936.

The computing device 910 may also have additional features or functionality. For example, the computing device 910 may also include additional data storage devices (removable and/or non-removable). Implementations of the computing device 910 that are stationary computing devices may include, for example, magnetic disks, optical disks, or tape, while implementations of the computing device 910 that are mobile computing devices may include, for example, compact flash cards. Such additional storage is illustrated in FIG. 9 by removable storage 940 and non-removable storage 950. Computer storage media may include volatile and non-volatile, removable and non-removable media implemented in any method or technology for storage of information, such as computer readable instructions, data structures, program modules or other data. The system memory 930, the removable storage 940 and the non-removable storage 950 are all examples of computer storage media. Computer storage media includes, but is not limited to, RAM, ROM, EEPROM, flash memory or other memory technology or medium which can be used to store the desired information and which can be accessed by the computing device 910. Any such computer storage media may be part of the device 910. The computing device 910 may also have input device(s) 960. Implementations of the computing device 910 that are stationary computing devices may included, for example, a keyboard, mouse, pen, voice input device, touch input device, etc., while implementations of the computing device 910 that are mobile computing devices may included, for example, voice input device, touch input device, etc. Output device(s) 970 such as a display, speakers, etc. may also be included.

The computing device 910 also contains communication connection(s) 980 that allow the device to communicate with other computing devices 990, such as over a network or a wireless network. The communication connection(s) 980 is an example of communication media. Communication media typically embodies computer readable instructions, data structures, program modules or other data in a modulated data signal such as a carrier wave or other transport mechanism and includes any information delivery media. The term “modulated data signal” may include a signal that has one or more of its characteristics set or changed in such a manner as to encode information in the signal. By way of example, and not limitation, communication media may include wired media such as a wired network or direct-wired connection, and wireless media such as acoustic, RF, infrared, magnetic and other wireless media. The term computer readable media as used herein includes both storage media and communication media.

The above specification, examples and data provide a complete description of the manufacture and use of the composition of the invention. Since many embodiments of the invention can be made without departing from the spirit and scope of the invention, the invention resides in the claims hereinafter appended.

We claim:

1. A system for receiving magnetic communication comprising:
a first antenna configured to receive a first magnetic signal;
a second antenna configured to receive the first magnetic signal, wherein the second antenna is oriented at an angle to the first antenna; and
a first control unit adapted to adjust a first receive gain of the first antenna and a second receive gain of the second antenna in response to an indication of signal quality detected at one of:
the first antenna;
the second antenna; and
the first antenna and the second antenna.

2. The system of claim 1, further comprising:
a transmission system operably coupled with the first antenna and the second antenna and configured to transmit a second magnetic signal via one of:
the first antenna;
the second antenna;
the first antenna and the second antenna; and
a third antenna configured to receive the second magnetic signal.

3. The system of claim 2, wherein a transmit power of the transmission system is adjusted in response to one of:
the first receive gain;
the second receive gain; and
the first receive gain and the second receive gain.

4. The system of claim 2, wherein:
the first control unit is adapted to adjust the first receive gain in response to the indication of signal quality detected at the first antenna and adjust the second receive gain in response to the indication of signal quality detected at the second antenna; and
the transmission system is adapted to adjust a transmit power of the first antenna in response to the indication of signal quality detected at the first antenna and adjust a transmit power of the second antenna in response to the indication of signal quality detected at the second antenna.

5. The system of claim 1, further comprising a first resonance adjustment system, configured to adjust a resonance frequency of at least one selected antenna, wherein the selected antenna includes of:
the first antenna; and
the second antenna.

6. The system of claim 5, wherein the first resonance adjustment system includes at least one variable capacitor coupled with the selected antenna wherein the first resonance adjustment system is configured to adjust a capacitance of the variable capacitor to adjust the resonance frequency of the selected antenna.

7. The system of claim 6, wherein the variable capacitor is a variable microelectromechanical systems capacitor.

8. The system of claim 6, further comprising a second resonance adjustment system, configured to adjust a resonance frequency of the third antenna.

9. The system of claim 8, wherein the second resonance adjustment system includes at least one additional variable capacitor coupled with the third antenna wherein the second resonance adjustment system is configured to adjust a capacitance of the additional variable capacitor to adjust the resonance of the third antenna.

10. The system of claim 1, wherein the indication of the signal quality of the magnetic signal received at the first antenna further comprises an indication of received signal strength.

11. A method of adjusting operating characteristics of a first antenna and a second antenna to receive magnetic signals transmitted by a third antenna, comprising:
transmitting a first magnetic signal from the first antenna;
receiving the first magnetic signal at the third antenna;
transmitting a second magnetic signal from the second antenna;
receiving the second magnetic signal at the third antenna;
adjusting a gain of the first antenna in response to an indication of signal quality of the first magnetic signal received at the third antenna; and
adjusting a gain of the second antenna in response to an indication of signal quality of the second magnetic signal received at the third antenna.

12. The method of claim 11, further comprising adjusting a resonance frequency of an antenna selected from a group comprising the first antenna, the second antenna and the third antenna.

13. The method of claim 12, wherein the adjusting the resonance frequency of the selected antenna comprises:
providing a variable capacitor coupled to the first antenna;
applying a signal to the first antenna;
measuring a resulting voltage across the first antenna; and
adjusting the variable capacitor to maximize the resulting voltage across the first antenna.

14. The method of claim 13, wherein the providing a variable capacitor includes providing a variable microelectromechanical systems capacitor coupled to the first antenna.

15. The method of claim 11, further comprising:
transmitting a third magnetic signal from the third antenna; and
receiving the third magnetic signal at the first antenna and the second antenna.

16. The system of claim 11, wherein the indication of received signal quality of the magnetic signal received at the first antenna further comprises an indication of received signal strength.

17. The system of claim 11, wherein the indication of received signal quality of the magnetic signal received at the first antenna further comprises a bit error rate.

18. A method of using a first antenna to communicate a magnetic signal, the method comprising:
providing a variable capacitor coupled to a first antenna;
applying a signal to the first antenna;
measuring a resulting voltage across the first antenna;
adjusting the variable capacitor to maximize the resulting voltage across the first antenna; and
communicating the magnetic signal with the antenna.

19. The method of claim 18, wherein the providing a variable capacitor includes providing a variable microelectromechanical systems capacitor coupled to the first antenna.

20. The method of claim 18, wherein the communicating the magnetic signal includes:
transmitting the magnetic signal from the first antenna to a second antenna and a third antenna;
receiving the magnetic signal at the second antenna and the third antenna;
adjusting a first receive gain of the second antenna in response to an indication of a signal quality detected at the first antenna; and
adjusting a second receive gain of the third antenna in response to an indication of a signal quality detected at the third antenna.
